(19) United States
(12) Patent Application Publication
(10) Pub. No.: US 2026/0190343 A1
(43) Pub. Date: Jul. 2, 2026

(54) NON-VOLATILE MEMORY DEVICE

(71) Applicant: Samsung Electronics Co., Ltd., Suwon-si (KR)

(72) Inventors: Ryoongbin Lee, Suwon-si (KR); Nakjin Son, Suwon-si (KR); Sangjae Lee, Suwon-si (KR); Jaeduk Lee, Suwon-si (KR); Jaehoon Lee, Suwon-si (KR)

(21) Appl. No.: 19/254,106

(22) Filed: Jun. 30, 2025

(30) Foreign Application Priority Data
Dec. 26, 2024 (KR) 10-2024-0197380

(51) Int. Cl. H10B 43/40; H10B 41/41

(52) U.S. Cl. CPC H10B 43/40; H10B 41/41

(57) ABSTRACT

A nonvolatile memory device includes a peripheral circuit including a first transistor and a second transistor. The first transistor and the second transistor are each on an active region of a substrate. The first transistor includes: a channel layer, a first gate dielectric layer, a metal layer, a first electrode layer, a first gate capping pattern, and a first offset spacer on sidewalls of the channel layer, the first gate dielectric layer, the metal layer, the first electrode layer, and the first gate capping pattern. The second transistor includes: a second gate dielectric layer, a second electrode layer, a second gate capping pattern, a second offset spacer on sidewalls of the second electrode layer and the second gate capping pattern; and a third offset spacer on the second offset spacer. The first offset spacer and the third offset spacer extend conformally.

### CROSS-REFERENCE TO RELATED APPLICATION

This application is based on and claims priority under 35 USC § 119 to Korean Patent Application No. 10-2024-0197380, filed on Dec. 26, 2024, in the Korean Intellectual Property Office, the disclosure of which is incorporated by reference herein in its entirety.

### TECHNICAL FIELD

The inventive concept relates to a nonvolatile memory device and an electronic system including the same. More particularly, the inventive concept relates to a nonvolatile memory device including a transistor and an electronic system including the same.

### BACKGROUND

In electronic systems requiring data storage, nonvolatile memory devices capable of storing large amounts of data, such as flash memory devices, have been proposed. Flash memory devices may include transistors, such as high-voltage transistors.

### SUMMARY

The inventive concept provides a nonvolatile memory device with improved electrical reliability and performance.

In addition, the problems to be solved by the inventive concept are not limited to the problems mentioned above, and other problems may be clearly understood by those skilled in the art from the description below.

To achieve the technical problem, the inventive concept provides the following nonvolatile memory device.

According to an aspect of the inventive concept, there is provided a nonvolatile memory device including a peripheral circuit including a first transistor and a second transistor, wherein the first transistor and the second transistor are each on an active region of a substrate, wherein the first transistor includes a channel layer on the active region, a first gate dielectric layer on the channel layer, a metal layer on the first gate dielectric layer, a first electrode layer on the metal layer, and a first gate capping pattern on the first electrode layer, and a first offset spacer n sidewalls of the channel layer, the first gate dielectric layer, the metal layer, the first electrode layer, and the first gate capping pattern, and extending on an upper surface of the active region. The second transistor includes a second gate dielectric layer on the active region, a second electrode layer on the second gate dielectric layer, a second gate capping pattern on the second electrode layer, a second offset spacer on sidewalls of the electrode layer and the second gate capping pattern and extending on an upper surface of the second gate dielectric layer, and a third offset spacer on the second offset spacer; the first offset spacer and the third offset spacer extend conformally.

According to another aspect of the inventive concept, there is provided a nonvolatile memory device including a peripheral circuit comprising a substrate, a memory cell array on the peripheral circuit. The peripheral circuit includes a first transistor and a second transistor spaced apart from each other and on an active region defined by a device isolation film on the substrate. The first transistor includes a first gate structure on the active region, a first offset spacer extending in a first direction parallel to an upper surface of the substrate on an upper surface of the active region and extending in a second direction perpendicular to the first direction on a sidewall of the first gate structure, and a first gate spacer on a sidewall of the first offset spacer. The second transistor includes a gate dielectric layer on the active region, a second gate structure on the gate dielectric layer, a second offset spacer extending in the first direction on an upper surface of the gate dielectric layer and extending in the second direction on a sidewall of the second gate structure, a third offset spacer between the second offset spacer and the second gate structure, between the second offset spacer and the gate dielectric layer, and a second gate spacer on a sidewall of the second offset spacer opposite the sidewall of the first offset spacer in the first direction, and an interface film between the second offset spacer and the third offset spacer. The first offset spacer and the second offset spacer extend conformally.

According to another aspect of the inventive concept, there is provided a nonvolatile memory device including a peripheral circuit including a plurality of transistors on a substrate and a memory cell array controlled by the peripheral circuit. The plurality of transistors include a first transistor and a second transistor. The first transistor and the second transistor each include a first gate structure and a second gate structure extending in a first direction parallel to the substrate on an active region defined by a device isolation film on the substrate. The first gate structure and second gate structure are spaced apart from each other in a second direction intersecting the first direction. The first gate structure and the second gate structure each include an electrode layer including a polysilicon electrode and a gate capping pattern on the electrode layer. The first transistor includes a first offset spacer extending along a sidewall of the first gate structure in a third direction perpendicular to the first direction and the second direction and extending along an upper surface of the active region in the second direction, and a gate spacer on a sidewall of the first offset spacer, the second transistor includes a second offset spacer having a thickness in a range of 10 Å to 70 Å, extending along a sidewall of the second gate structure in the third direction, an upper surface of the active region, a third offset spacer on the second offset spacer, and a gate spacer on the third offset spacer. A first thickness of the first offset spacer and a third thickness of the third offset spacer are in the range of 10 Å to 70 Å and the first offset spacer and the third offset spacer extend conformally, an interface film is between the third offset spacer and the second offset spacer, and a residual offset spacer is between the first offset spacer and a sidewall and an upper surface of the gate capping pattern in the first gate structure.

According to another aspect of the inventive concept, there is provided a method of manufacturing a nonvolatile memory device including preparing a substrate including a first active region and a second active region defined by a device isolation film, forming a pre-channel layer on the first active region and forming a pre-gate dielectric layer covering all of the pre-channel layer of the first active region, an upper surface of the second active region, and an upper surface of the device isolation film, forming a pre-metal layer on the pre-gate dielectric layer of the first active region and forming a pre-electrode layer on the pre-metal layer of the first active region and the pre-gate dielectric layer of the second active region, forming a first gate capping pattern on the pre-electrode layer of the first active region and forming a second gate capping pattern on the pre-electrode layer of the second active region, etching a portion of the pre-electrode layer using the second gate capping pattern as an etching mask in the second active region and forming a first offset spacer layer covering the first and second active regions with a conformal thickness, removing a portion of the first offset spacer layer in the second active region to form a first offset spacer, removing the first offset spacer layer in the first active region and etching portions of the pre-electrode layer, the metal layer, the gate dielectric layer, and the pre-channel layer using the first gate capping pattern as an etching mask so that an upper surface of the first active region is exposed, and forming a second offset spacer integrally extending across the first and second active regions, wherein an interface film is included between the first offset spacer and the second offset spacer disposed on the second active region.

### BRIEF DESCRIPTION OF THE DRAWINGS

Embodiments of the present disclosure are more clearly understood from the following detailed description taken in conjunction with the accompanying drawings in which:

FIG. 1 is a block diagram of a nonvolatile memory device according to embodiments;

FIG. 2 is a schematic perspective view of a nonvolatile memory device according to embodiments;

FIG. 3 is an equivalent circuit diagram of a memory cell array MCA of a nonvolatile memory device according to embodiments;

FIG. 4 is a schematic plan view of a portion of a nonvolatile memory device according to embodiments;

FIGS. 5 to 7 are diagrams illustrating a nonvolatile memory device according to embodiments in detail;

FIG. 8 is a cross-sectional view illustrating a transistor included in a nonvolatile memory device according to embodiments;

FIGS. 9, 10, 11, 12, 13, 14A, 14B, 15, 16, and 17 are cross-sectional views illustrating a method of manufacturing a transistor included in a nonvolatile memory device, according to embodiments, in which FIGS. 9, 10, 11, 12, 13, 15, and 16 are cross-sectional views sequentially illustrating a method of manufacturing the transistors illustrated in FIG. 8, FIGS. 14A and 14B are enlarged views of EX1 and EX2 of FIG. 13, respectively, and FIG. 17 is another enlarged view of EX1 of FIG. 13;

FIG. 18 is a schematic diagram illustrating an electronic system including a nonvolatile memory device according to embodiments;

FIG. 19 is a perspective view schematically illustrating an electronic system including a nonvolatile memory device according to embodiments; and

FIG. 20 is a cross-sectional view schematically illustrating semiconductor packages according to embodiments.

### DETAILED DESCRIPTION OF THE EMBODIMENTS

Hereinafter, embodiments are described in detail with reference to the accompanying drawings. Like reference numerals denote like components in the drawings, and redundant descriptions thereof are omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

The inventive concept may include various modifications and embodiments, and certain embodiments are illustrated in the drawings and are described in detail in the detailed description. However, it should be understood that the inventive concept is not limited to the embodiments, but includes all modifications, equivalents, and substitutes included in the technical scope of the inventive concept. In the following description of the inventive concept, a detailed description of known functions and configurations incorporated herein will be omitted when it may make the subject matter of the inventive concept rather unclear.

As used herein, two elements that “extend integrally” or are “integrally formed” may extend conformally and may be formed of the same material and/or may be formed together out of a common process or operation. Elements that have or extend in an ‘L’ shape may extend in a first direction and in a second direction perpendicular to the first direction.

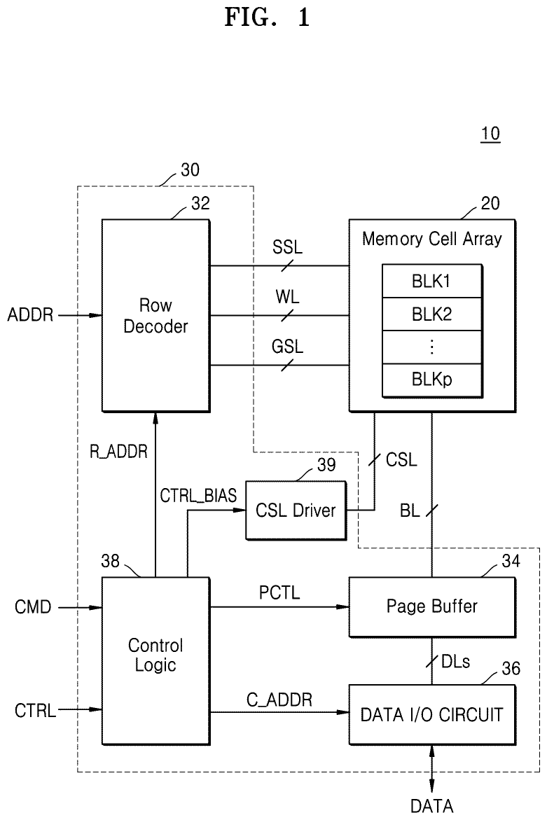

FIG. 1 is a block diagram of a nonvolatile memory device 10 according to embodiments.

In embodiments, the nonvolatile memory device 10 may include a memory cell array 20 and a peripheral circuit 30. The memory cell array 20 may be controlled by the peripheral circuit 30. The memory cell array 20 may include a plurality of memory cell blocks BLK1, BLK2, . . . , BLKp. Each of the memory cell blocks BLK1, BLK2, . . . , BLKp may include a plurality of memory cells. The memory cell blocks BLK1, BLK2, . . . , BLKp may be connected to the peripheral circuit 30 via bit lines BL, word lines WL, string select lines SSL, and ground select lines GSL.

The peripheral circuit 30 may include a row decoder 32, a page buffer 34, a data I/O circuit 36, control logic 38, and a common source line driver 39. The peripheral circuit 30 may further include various circuits, such as a voltage generating circuit that generates various voltages necessary for the operation of the nonvolatile memory device 10, an error correction circuit that corrects errors in data read out from the memory cell array 20, and an input/output interface.

In some embodiments, each component constituting the peripheral circuit 30 may include a plurality of transistors, such as metal-oxide-semiconductor (MOS) transistors. In some embodiments, each component constituting the peripheral circuit 30 may include a plurality of transistors, for example, high-voltage transistors. In some embodiments, the high-voltage transistors may refer to transistors having a breakdown voltage of 5 V to 10 V or a breakdown voltage higher than 10 V.

The memory cell array 20 may be connected to the row decoder 32 through a word line WL, a string select line SSL, and a ground select line GSL and may be connected to the page buffer 34 through a bit line BL. In the memory cell array 20, memory cells included in the memory cell blocks BLK1, BLK2, . . . , BLKp may be flash memory cells. The memory cell array 20 may include a three-dimensional (3D) memory cell array. The 3D memory cell array may include a plurality of NAND strings, each of which may include a plurality of memory cells connected to a plurality of vertically stacked word lines WL.

The peripheral circuit 30 may receive an address ADDR, a command CMD, and a control signal CTRL from the outside of the nonvolatile memory device 10 and may transmit and receive data to and from a device outside the nonvolatile memory device 10. The row decoder 32 may select at least one of the memory cell blocks BLK1, BLK2, . . . , BLKp in response to an address ADDR from the outside, and select a word line WL, a string select line SSL, and a ground select line GSL of the selected memory cell block. The row decoder 32 may transmit a voltage for performing a memory operation to the word line WL of the selected memory cell block.

The page buffer 34 may be connected to the memory cell array 20 through the bit line BL. During a program operation, the page buffer 34 may operate as a write driver to apply a voltage according to the data DATA to be stored in the memory cell array 20 to the bit line BL, and during a read operation, the page buffer 34 may operate as a sense amplifier to sense the data DATA stored in the memory cell array 20. The page buffer 34 may operate according to a control signal PCTL provided from the control logic 38.

The data I/O circuit 36 may be connected to the page buffer 34 through a plurality of data lines DLs. During the program operation, the data I/O circuit 36 may receive the data DATA from a memory controller (not shown) and provide program data DATA based on a column address C_ADDR provided from the control logic 38 to the page buffer 34. During a read operation, the data I/O circuit 36 may provide the read data DATA stored in the page buffer 34 to the memory controller based on the column address C_ADDR provided from the control logic 38.

The data I/O circuit 36 may transmit an input address or command to the control logic 38 or the row decoder 32. The peripheral circuit 30 may further include an electrostatic discharge (ESD) circuit and a pull-up/pull-down driver.

The control logic 38 may receive a command CMD and a control signal CTRL from the memory controller. The control logic 38 may provide a row address R_ADDR to the row decoder 32 and provide the column address C_ADDR to the data I/O circuit 36. The control logic 38 may generate various internal control signals used in the nonvolatile memory device 10 in response to the control signal CTRL. For example, the control logic 38 may adjust a voltage level provided to the word line WL and the bit line BL when performing a memory operation such as the program operation or an erase operation.

The common source line driver 39 may be connected to the memory cell array 20 through a common source line CSL. The common source line driver 39 may apply a common source voltage (e.g., a power source voltage) or a ground voltage to the common source line CSL based on a bias signal CTRL_BIAS from the control logic 38.

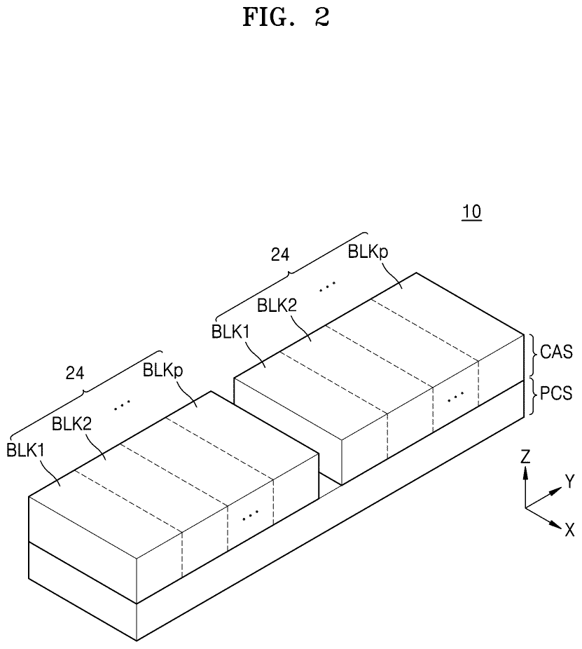

FIG. 2 is a schematic perspective view of the nonvolatile memory device 10 according to embodiments.

In embodiments, the nonvolatile memory device 10 may include a cell array structure CAS and a peripheral circuit structure PCS that overlap each other in a vertical direction (a Z direction or third direction). The cell array structure CAS may include the memory cell array 20 of FIG. 1.

In some embodiments, the peripheral circuit structure PCS may include a plurality of transistors, such as MOS transistors. In some embodiments, the peripheral circuit structure PCS may include a plurality of transistors, such as high-voltage transistors. In some embodiments, the high-voltage transistors may refer to transistors having a breakdown voltage of 5 to 10 V or a breakdown voltage higher than 10 V. The peripheral circuit structure PCS may include the peripheral circuit 30 of FIG. 1.

The cell array structure CAS may include a plurality of tiles 24. Each of the tiles 24 may include a plurality of memory cell blocks BLK1, BLK2, . . . , BLKp. Each of the memory cell blocks BLK1, BLK2, . . . , BLKp may include memory cells arranged three-dimensionally.

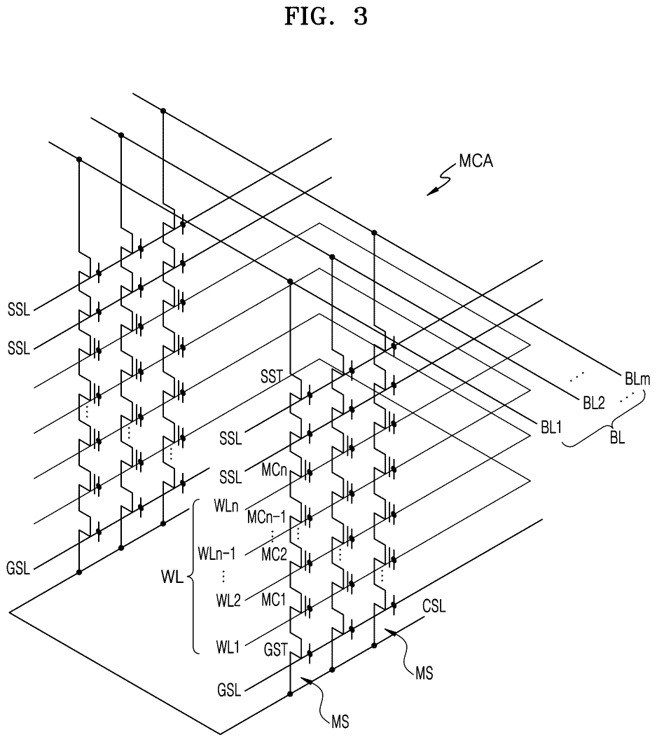

FIG. 3 is an equivalent circuit diagram of a memory cell array MCA of a nonvolatile memory device according to embodiments.

In detail, FIG. 3 illustrates an equivalent circuit diagram of a vertical NAND flash memory device having a vertical channel structure. The memory cell blocks BLK1, BLK2, . . . , BLKp of FIGS. 1 and 2 may each include the memory cell array MCA having a circuit configuration illustrated in FIG. 3.

The memory cell array MCA may include a plurality of memory cell strings MS. The memory cell array MCA may include a plurality of bit lines BL or BL1, BL2, . . . , BLm, a plurality of word lines WL or WL1, WL2, . . . , WLn−1, WLn, at least one string select line SSL, at least one ground select line GSL, and a common source line CSL.

The plurality of memory cell strings MS may be formed between the bit line BL and the common source line CSL. FIG. 3 illustrates a case in which each of the memory cell strings MS includes one ground select line GSL and two string select lines SSL, but the inventive concept is not limited thereto. For example, each of the memory cell strings MS may include one string select line SSL.

The memory cell strings MS may each include a string select transistor SST, a ground select transistor GST, and a plurality of memory cell transistors MC1, MC2, . . . , MCn−1, MCn. A drain region of the string select transistor SST may be connected to the bit line BL, and a source region of the ground select transistor GST may be connected to the common source line CSL. The common source line CSL may be a region in which source regions of a plurality of ground select transistors GST are commonly connected.

A string select transistor SST may be connected to the string select line SSL, and the ground select transistor GST may be connected to the ground select line GSL. The plurality of memory cell transistors MC1, MC2, . . . , MCn−1, MCn may be connected to the word lines WL, respectively.

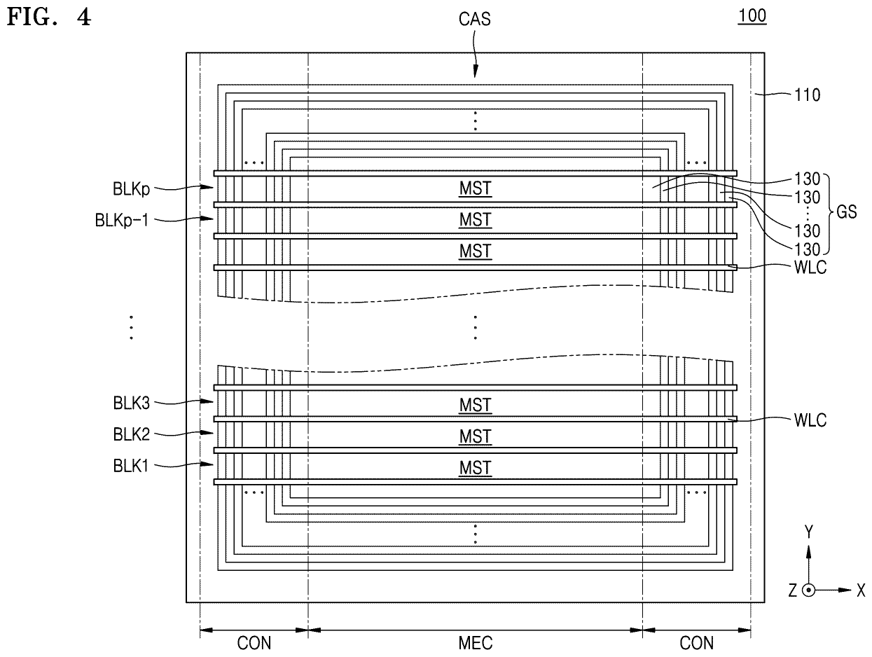

FIG. 4 is a schematic plan view of a portion of a nonvolatile memory device 100 according to embodiments.

In embodiments, a cell array structure CAS of the nonvolatile memory device 100 may include an upper substrate 110 and a plurality of memory cell blocks BLK1, BLK2, . . . , BLKp arranged on the upper substrate 110.

The peripheral circuit structure PCS as shown in FIG. 2 may be placed below the upper substrate 110. The plurality of memory cell blocks BLK1, BLK2, . . . , BLKp may overlap the peripheral circuit structure PCS with the upper substrate 110 therebetween in the vertical direction (the Z direction or third direction). The peripheral circuit structure PCS positioned below the upper substrate 110 may include the peripheral circuit 30 of FIG. 1.

The cell array structure CAS may include a memory cell region MEC and connection regions CON arranged on opposite sides of the memory cell region MEC in a first horizontal direction (an X direction). Each of the plurality of memory cell blocks BLK1, BLK2, . . . , BLKp may include a memory stack structure MST extending in the first horizontal direction (the X direction) across the memory cell region MEC and the connection region CON.

The memory stack structure MST may include a plurality of gate lines 130 stacked to overlap each other in the vertical direction (the Z direction) in the memory cell region MEC and the connection region CON on the upper substrate 110. In each of the plurality of memory stack structures MST, the plurality of gate lines 130 may form a gate stack GS.

In each of the plurality of memory stack structures MST, the plurality of gate lines 130 may form the ground select line GSL, a plurality of word lines WL, and the string select line SSL of FIG. 3. The area of the plurality of gate lines 130 in the X-Y plane may gradually decrease as a distance from the upper substrate 110 increases. The central portion of each of the plurality of gate lines 130 that overlap each other in the vertical direction (the Z direction or third direction) may form the memory cell region MEC, and the edge portion of each of the plurality of gate lines 130 may form the connection region CON.

A plurality of word line cut structures WLC extending in the first horizontal direction (the X direction) in the memory cell region MEC and the connection region CON may be arranged on the upper substrate 110. The plurality of word line cut structures WLC may be arranged apart from each other in a second horizontal direction (a Y direction). The plurality of memory cell blocks BLK1, BLK2, . . . , BLKp may be placed one by one between each of the plurality of word line cut structures WLC.

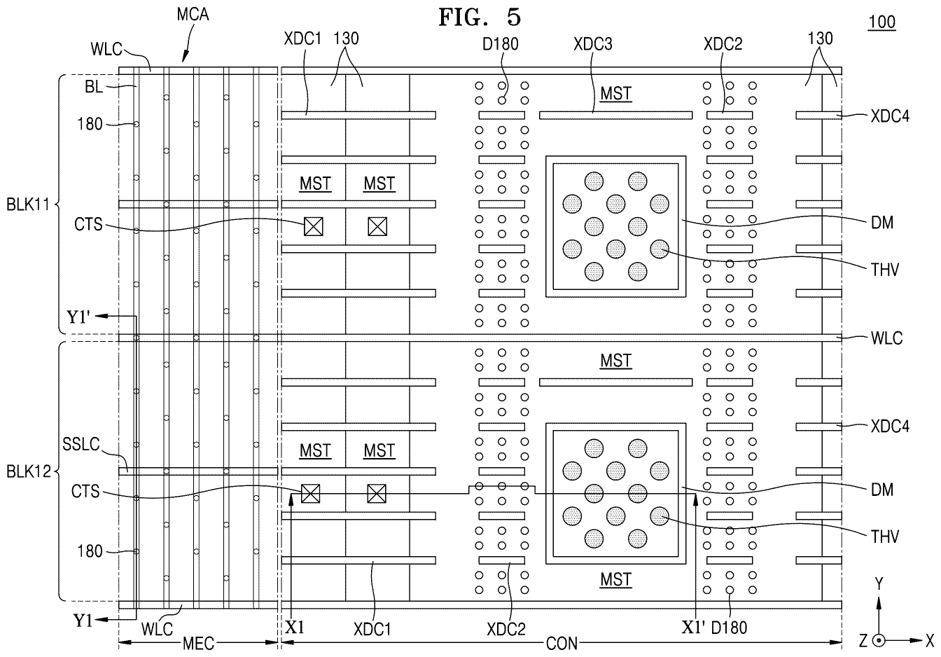

FIGS. 5 to 7 are diagrams illustrating in detail the nonvolatile memory device 100 according to embodiments.

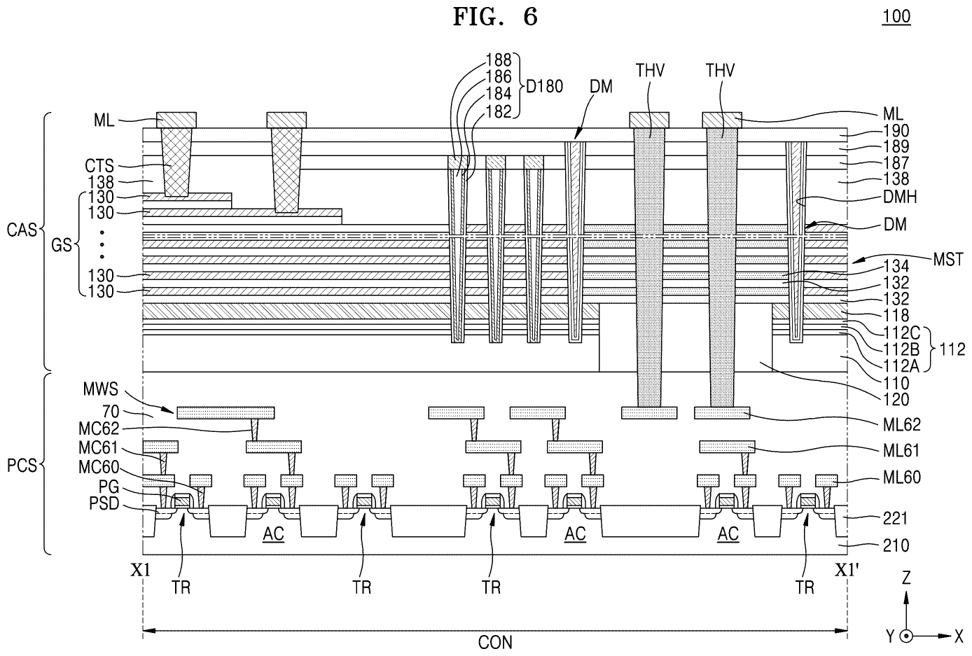

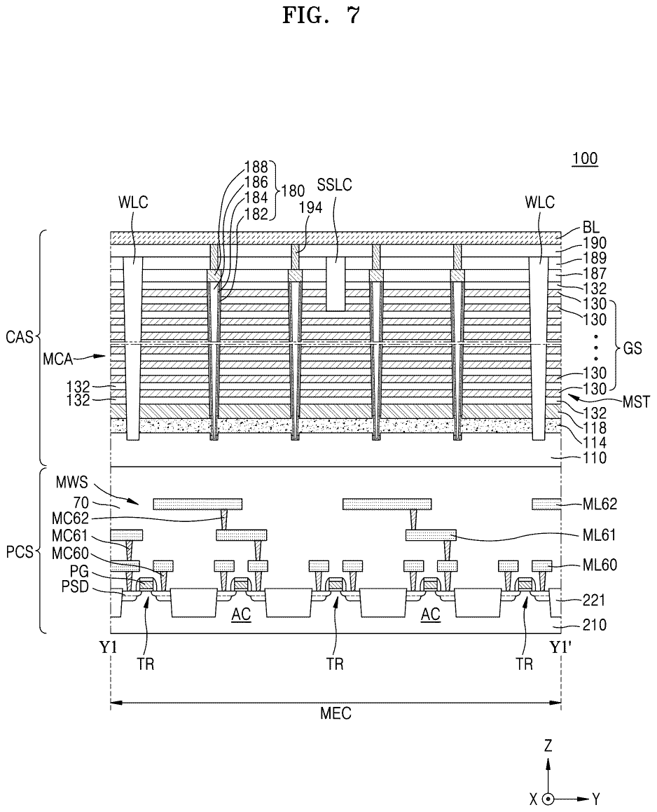

In detail, FIG. 5 is a plan view illustrating a portion of the configuration of the memory cell blocks BLK11 and BLK12 that may constitute the plurality of memory cell blocks BLK1, BLK2, . . . , BLKp of FIG. 4. FIG. 6 is an enlarged cross-sectional view of some components taken along line X1-X1′ of FIG. 5. FIG. 7 is an enlarged cross-sectional view illustrating some components taken along line Y1-Y1′ of FIG. 5.

Referring to FIGS. 5 to 7, the nonvolatile memory device 100 may include a peripheral circuit structure PCS and the cell array structure CAS located above the peripheral circuit structure PCS and overlapping the peripheral circuit structure PCS in the vertical direction (the Z direction or third direction).

The cell array structure CAS may include the upper substrate 110, an insulating plate 112 including a first insulating plate 112A, a second insulating plate 112B, and a third insulating plate 112C, a first conductive plate 114, a second conductive plate 118, a hardmask layer 134, a call array insulating layer 138, a contact plug CTS, a through-hole via THV, a dummy structure DM, a dummy hole DMH, a top metal layer ML, a first capping layer 187, a second capping layer 189, a third capping layer 190, and the memory stack structure MST. In the memory cell region MEC of the cell array structure CAS, a first conductive plate 114, a second conductive plate 118, and the memory stack structure MST may be sequentially stacked on the upper substrate 110. In the connection region CON of the cell array structure CAS, an insulating plate 112, the second conductive plate 118, and the memory stack structure MST may be sequentially stacked on the upper substrate 110. The PCS may include a peripheral insulating layer 70, a peripheral source/drain region PSD, a peripheral gate PC, a metal wiring stack MWS, a first contact pattern MC60, a second contact pattern MC61, a first metal pattern ML60, a second metal pattern ML61, a third metal pattern ML62, and a third contact pattern MC62. The nonvolatile memory device 100 comprises a first upper contact XDC1, a second upper contact XDC2, a third upper contact XDC3, and a fourth upper contact XDC4.

The first conductive plate 114 and the second conductive plate 118 may perform a function of the common source line CSL of FIG. 3. The first conductive plate 114 and the second conductive plate 118 may function as source regions that supply current to vertical memory cells included in the cell array structure CAS.

In some embodiments, the upper substrate 110 may include a semiconductor material, such as polysilicon. The first conductive plate 114 and the second conductive plate 118 may each include a doped polysilicon film, a metal film, or combinations thereof. The metal film may include, but is not limited to, tungsten (W).

The memory stack structure MST may include a gate stack GS. The gate stack GS may include the plurality of gate lines 130 extending parallel to each other in the first horizontal direction (the X direction) and overlapping each other in the vertical direction (the Z direction or third direction). Each of the plurality of gate lines 130 may include metal, metal silicide, a semiconductor doped with impurities, or combinations thereof. For example, the plurality of gate lines 130 may each include a metal, such as tungsten, nickel, cobalt, tantalum, etc., a metal silicide, such as tungsten silicide, nickel silicide, cobalt silicide, tantalum silicide, etc., doped polysilicon, or combinations thereof.

An insulating film 132 may be located between the second conductive plate 118 and the plurality of gate lines 130 and between each of the plurality of gate lines 130. Among the plurality of gate lines 130, the uppermost gate line 130 may be at least partially covered with the insulating film 132. The insulating film 132 may include silicon oxide.

The plurality of word line cut structures WLC may extend in the first horizontal direction (the X direction) on the upper substrate 110 in the memory cell region MEC and the connection region CON. The width of each of the plurality of gate lines 130 included in the memory cell blocks BLK11 and BLK12 in the second horizontal direction (Y direction) may be limited by the plurality of word line cut structures WLC.

Each of the plurality of word line cut structures WLC may include an insulating structure. In some embodiments, the insulating structure may include silicon oxide, silicon nitride, silicon oxynitride, or a low-k material. For example, the insulating structure may include a silicon oxide film, a silicon nitride film, a SiON film, a SiOCN film, a SiCN film, or combinations thereof. In some embodiments, at least a portion of the insulating structure may include an air gap. The term “air” as used herein may refer to the atmosphere or other gases that may be present during a manufacturing process.

The plurality of gate lines 130 constituting one gate stack GS may be stacked on the second conductive plate 118 between two adjacent word line cut structures WLC to overlap each other in the vertical direction (Z direction). The plurality of gate lines 130 constituting one gate stack GS may include the ground select line GSL, a plurality of word lines WL, and the string select line SSL of FIG. 3.

As illustrated in FIG. 7, among the plurality of gate lines 130, two upper gate lines 130 may be separated in the second horizontal direction (Y direction) with a string select line cut structure SSLC therebetween. The two gate lines 130 separated from each other with the string select line cut structure SSLC therebetween may each form the string select line SSL as described above with reference to FIG. 3.

In FIG. 7, a case in which one string select line cut structure SSLC is formed in one gate stack GS is illustrated but the inventive concept is not limited to that illustrated in FIG. 7. For example, at least two string select line cut structures SSLC may be formed in one gate stack GS. The string select line cut structure SSLC may be filled with an insulating film. In some embodiments, the string select line cut structure SSLC may include an insulating film including an oxide film, a nitride film, or combinations thereof. In some embodiments, at least a portion of the string select line cut structure SSLC may include an air gap.

As illustrated in FIGS. 5 and 7, a plurality of channel structures D180 may extend in the vertical direction (the Z direction or third direction) through the plurality of gate lines 130, a plurality of insulating films 132, the second conductive plate 118, and the first conductive plate 114 on the upper substrate 110 in the memory cell region MEC. The plurality of channel structures D180 may be arranged apart from each other at a certain interval in the first horizontal direction (X direction) and the second horizontal direction (the Y direction). Each of the plurality of channel structures D180 may include a gate dielectric film 182, a channel region 184, a buried insulating film 186, and a drain region 188.

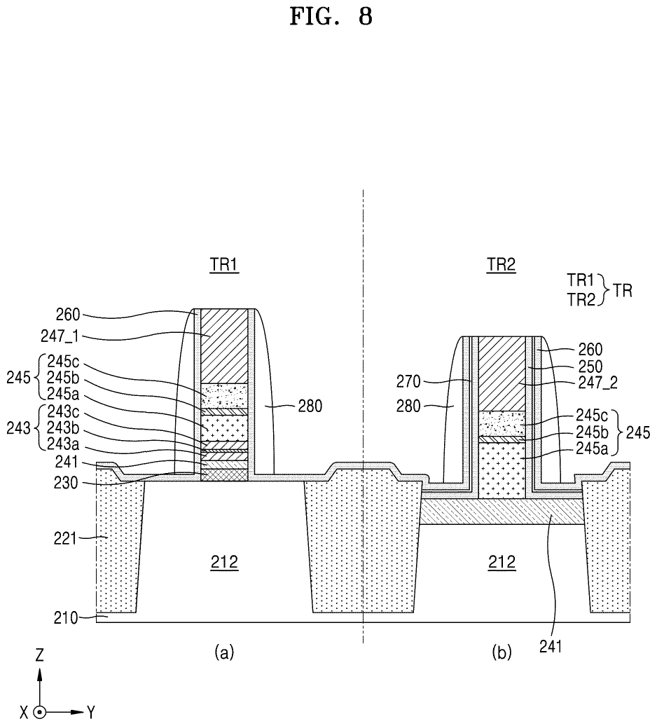

FIG. 8 is a cross-sectional view illustrating first and second transistors TR1 and TR2 included in the nonvolatile memory device 10 or 100 according to embodiments.

In embodiments, the first transistor TR1 shown in region (a) of FIG. 8 and the second transistor TR2 shown in region (b) of FIG. 8 may be components included in the transistor TR included in the peripheral circuit structure PCS of the nonvolatile memory device 10 or 100 described above. In FIG. 8 and the subsequent drawings, the first transistor TR1 and the second transistor TR2 are illustrated as being directly apart from each other in the second horizontal direction (the Y direction), but this is only for convenience of description, and the arrangement of the first transistor TR1 and the second transistor TR2 is not limited thereto.

Referring to FIG. 8, in the first transistor TR1 and the second transistor TR2, structures of stacks stacked on an active region 212 may be different and structures and thicknesses of offset spacers may also be different. In embodiments, the first transistor TR1 may be a low voltage (LV) transistor and the second transistor TR2 may be a high voltage (HV) transistor.

In embodiments, the first transistor TR1 may include a channel layer 230, a gate dielectric layer 241, a metal layer 243, an electrode layer 245, and a first gate capping pattern 247_1 that are sequentially stacked and arranged on the active region 212 and may further include a second offset spacer 260 that surrounds a sidewall of the stacked structure and extends to an upper surface of the active region 212 to have an ‘L’ shape. In addition, in some embodiments, a gate spacer 280 may be additionally formed on the second offset spacer 260. In embodiments, the gate spacer 280 may include an oxide, for example, SiO₂, while the second offset spacer 260 may include SiN.

In embodiments, the second transistor TR2 may include the gate dielectric layer 241, the electrode layer 245, and a second gate capping pattern 247_2 sequentially formed on the active region 212 and may further include a first offset spacer 250 surrounding sidewalls of the electrode layer 245 and a second gate capping pattern 247_2 stacked on the gate dielectric layer 241 and extending to an upper surface of the gate dielectric layer 241 to have an ‘L’ shape, a second offset spacer 260 formed on the first offset spacer 250, and an interface film 270 located between the first offset spacer 250 and the second offset spacer 260. In addition, in some embodiments, the gate spacer 280 may be additionally formed on the second offset spacer 260. In embodiments, the gate spacer 280 may include an oxide, for example, SiO₂, while the second offset spacer 260 may include SiN.

In some embodiments, a height of the first transistor TR1 in the vertical direction (the Z direction or third direction) may be greater than a height of the second transistor TR2 in the vertical direction (the Z direction or third direction).

In embodiments, referring to region (a), the second offset spacer 260 may be formed to be laterally symmetrical with respect to the first transistor TR1, and referring to region (b), the first offset spacer 250 and the second offset spacer 260 may be formed to be laterally symmetrical with respect to the second transistor TR2. That is, in the first transistor TR1, the second offset spacer 260 may extend along side surfaces of the gate dielectric layer 241, the metal layer 243, the electrode layer 245, and the first gate capping pattern 247_1 symmetrically in the second horizontal direction (the Y direction), and in the second transistor TR2, the first offset spacer 250 and second offset spacer 260 may extend along side surfaces of the electrode layer and the second gate capping pattern 247_2 symmetrically in the second horizontal direction (the Y direction).

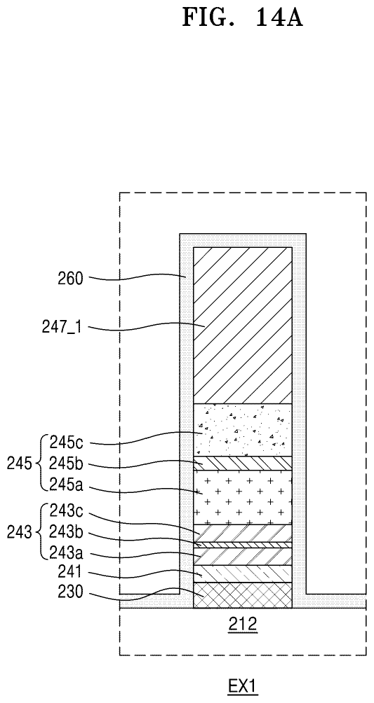

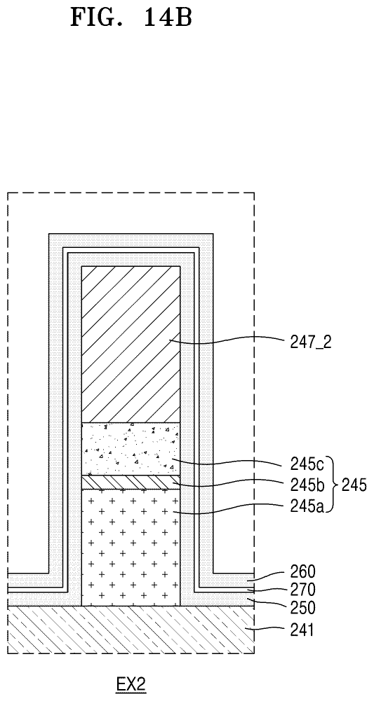

In particular, in region (b), because the offset spacers including SiN are stacked twice, the interface film 270 including SiO₂ may be located between the first offset spacer 250 and the second offset spacer 260, which is described in detail below with reference to FIG. 14B.

Referring back to FIG. 8, because only the second offset spacer 260 is formed in region (a), while the first and second offset spacers 250 and 260 are formed together in region (b), the thickness of the offset spacer included in the second transistor TR2 may be greater than the thickness of the offset spacer included in the first transistor TR1.

As illustrated in FIG. 8, the second offset spacer 260 of region (a) and the second offset spacer 260 of region (b) are connected at the boundary between region (a) and region (b) and may be formed with the same thickness in region (a) and region (b). That is, the second offset spacer 260 of region (a) may be formed integrally, e.g., at the same time as part of a common process or operation, with the second offset spacer 260 of region (b).

In the nonvolatile memory device 100 (see FIG. 7), it is important for the first transistor TR1 to secure maximum ON-current at limited OFF-current and minimizing RC delay is advantageous, whereas electrical reliability under high voltage is important for the second transistor TR2, and thus, the conditions required for the first transistor TR1 be different from the second transistor TR2. As a result, when considering the respective operating characteristics, it is advantageous for the second transistor TR2 to have a relatively thick offset spacer and for the first transistor TR1 to have a relatively thin offset spacer. Accordingly, the nonvolatile memory device 100 (see FIG. 7) according to the inventive concept may provide offset spacers with optimized thicknesses for each of the heterogeneous transistor devices, thereby improving the reliability of the devices.

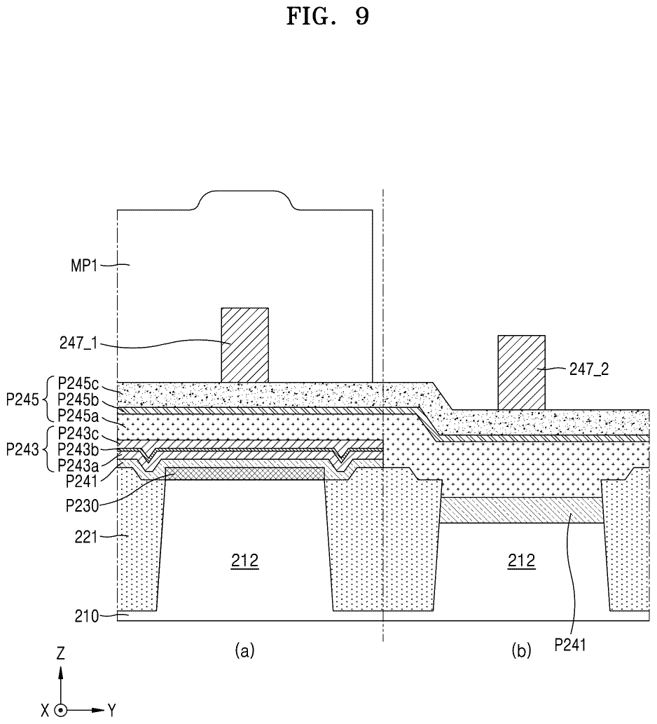

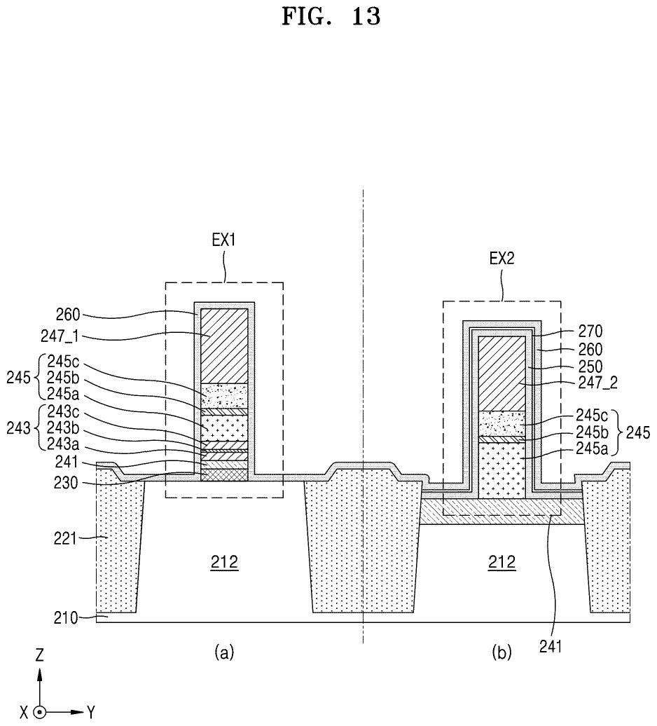

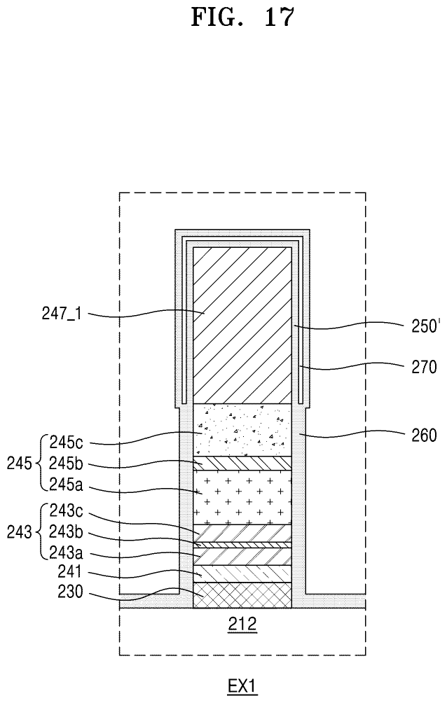

FIGS. 9, 10, 11, 12, 13, 14A, 14B, 15, 16, and 17 are cross-sectional views illustrating a method of manufacturing a transistor included in a nonvolatile memory device, according to an embodiment. In detail, FIGS. 9, 10, 11, 12, 13, 15, and 16 are cross-sectional views sequentially illustrating a method of manufacturing the first and second transistors TR1 and TR2 illustrated in FIG. 8, FIGS. 14A and 14B are enlarged views of EX1 and EX2 of FIG. 13, respectively, and FIG. 17 is another enlarged view of EX1 of FIG. 13.

Referring to FIG. 9, a device isolation film 221 may be placed on a substrate 210. Here, the active region 212 may be defined in the substrate 210 by the device isolation film 221. The device isolation film 221 may play a role in preventing electrons inside the active region 212 from flowing to other transistors or devices. According to embodiments, the device isolation film 221 may include silicon oxide. The device isolation film 221 may be placed within a device isolation trench.

A pre-gate dielectric layer P241 may be placed on the active region 212 of the substrate 210, and a pre-electrode layer P245 may be formed thereon. In embodiments, in region (a), a pre-metal layer P243 may additionally be located between the gate dielectric layer P241 and the pre-electrode layer P245. In addition, in some embodiments, when a PMOS transistor is included in region (a), a pre-channel layer P230 may be formed below the pre-gate dielectric layer P241 as illustrated in FIG. 9, but the inventive concept is not limited thereto. In region (a), a first gate capping pattern 247_1 may be placed on the pre-electrode layer P245, and in region (b), a second gate capping pattern 247_2 may be placed on the pre-electrode layer P245.

In embodiments, the pre-gate dielectric layer P241 may include an oxide, and the pre-channel layer P230 may include SiGe.

In embodiments, the pre-metal layer P243 may have a three-layer structure including a first pre-metal layer P243a, a second pre-metal layer P243b, and a third pre-metal layer P243c. For example, the first and third pre-metal layers P243a and P243c may include TiN and the second pre-metal layer P243b may include LaO, but the inventive concept is not limited thereto. The pre-metal layer P243 may extend in the second horizontal direction (the Y direction) only in region (a) and may not be formed in region (b).

In embodiments, the pre-electrode layer P245 may have a three-layer structure including a first pre-electrode layer P245a, a second pre-electrode layer P245b, and a third pre-electrode layer P245c. For example, the first pre-electrode layer P245a may include doped polysilicon, the second pre-electrode layer P245b may include TiSiN, and the third pre-electrode layer P245c may include W, but the inventive concept is not limited thereto. The pre-electrode layer P245 may extend in the second horizontal direction (the Y direction) across both region (a) and region (b), and a lower surface of the pre-electrode layer P245 in region (b) may be arranged on the same plane as an upper surface of the pre-gate dielectric layer P241.

In embodiments, the first and second gate capping patterns 247_1 and 247_2 may include SiN. The first and second gate capping patterns 247_1 and 247_2 may at least partially cover only portions of the upper surface of the pre-electrode layer P245 in regions a and b, respectively.

Referring back to FIG. 9, a first mask pattern MP1 covering at least a portion of region (a) may be formed. The first mask pattern MP1 may not be formed in region (b).

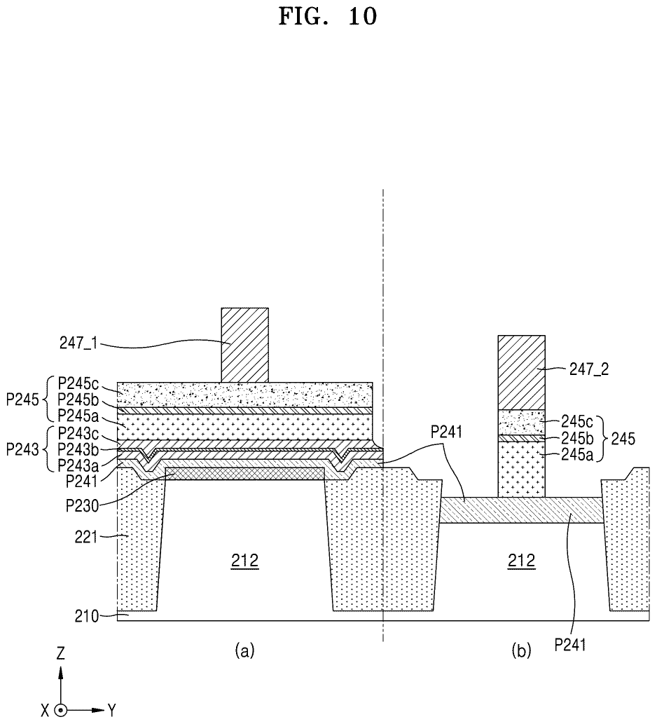

Referring to FIG. 10, in region (b), a portion of the pre-electrode layer P245 may be removed to form the electrode layer 245. In region (a), the pre-electrode layer P245 may be left as is by the first mask pattern MP1 (see FIG. 9). In embodiments, the electrode layer 245 may be obtained by removing a portion of the pre-electrode layer P245 using the second gate capping pattern 247_2 as an etching mask. By the process, a portion of the upper surface of the pre-gate dielectric layer P241 and the upper surface of the device isolation film 221 may be exposed in region (b).

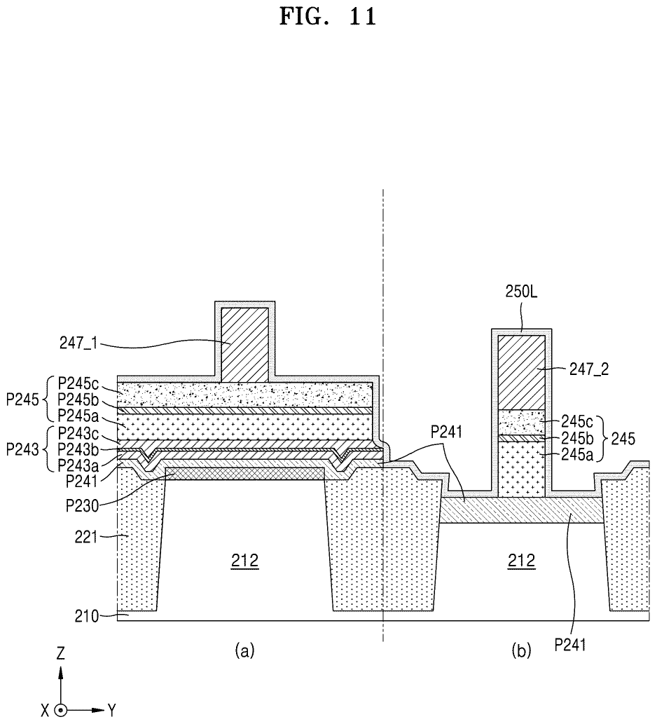

Referring to FIG. 11, a first offset spacer layer 250L may be formed across regions a and b. The first offset spacer layer 250L may surround the exposed upper surface and sidewalls of the pre-electrode layer P245, sidewalls of the pre-metal layer P243 and the pre-gate dielectric layer P241, and the upper surface and sidewalls of the first gate capping pattern 247_1 in region (a) and may surround the exposed upper surface of the pre-gate dielectric layer P241, the exposed surface of the device isolation film 221, sidewalls of the electrode layer 245, and the upper surface and sidewalls of the second gate capping pattern 247_2 in region (b).

In embodiments, the first offset spacer layer 250L may include SiN. In embodiments, the first offset spacer layer 250L may be formed with a conformal thickness. For example, the first offset spacer layer 250L may be formed with a thickness of 10 Å to 70 Å. For example, the first offset spacer layer 250L may be formed with a thickness of 30 Å, but the inventive concept is not limited thereto.

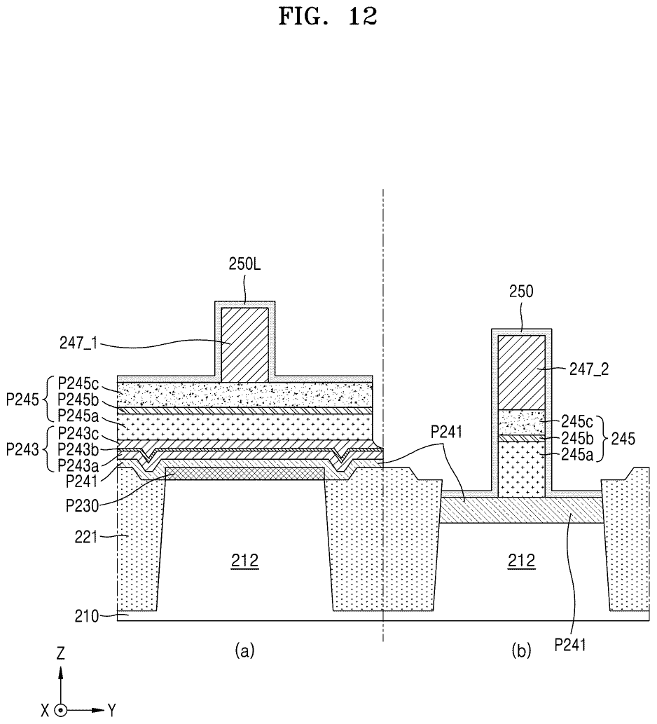

Referring to FIG. 12, the first offset spacer layer 250L may be removed from at least a portion in region (a) and at least a portion in region (b).

This may be a result of forming a mask pattern (not shown) in regions a and b of FIG. 11 and removing a portion of the first offset spacer layer 250L using the mask pattern as an etching mask. As a result, the first offset spacer layer 250L of region (a) may remain in a form that surrounds the upper surface of the pre-electrode layer P245 and the upper surface and sidewalls of the first gate capping pattern P247_1. In region (b), the first offset spacer 250 may remain as a result of removing a portion of the first offset spacer layer 250L. The first offset spacer 250 may be in a form that surrounds the exposed upper surface of the pre-gate dielectric layer P241, the sidewalls of the electrode layer 245, and the upper surface and sidewalls of the gate capping pattern P247_2 in region (b).

Referring to FIGS. 13, 14A, and 14B together, in region (a), the first offset spacer layer 250L may be removed, portions of the pre-electrode layer P245, the pre-metal layer P243, the pre-gate dielectric layer P241, and the pre-channel layer P230 may be etched using the first gate capping pattern P247_1 as an etching mask so that the upper surface of the active region 212 is exposed, and then, the second offset spacer 260 may be formed across region (a) and region (b). Here, the second offset spacer 260 of region (a) and the second offset spacer 260 of region (b) may include the same material and be formed with the same thickness. In addition, the second offset spacer 260 of region (a) and the second offset spacer 260 of region (b) may extend continuously even at the boundary between region (a) and region (b). That is, the second offset spacer 260 in region (a) and the second offset spacer 260 in region (b) may be flush with each other at the intersection of region (a) and region (b). The second offset spacer 260 may be formed simultaneously across region (a) and region (b). That is, the second offset spacer 260 of region (a) may be formed integrally, e.g., at the same time as part of a common process or operation, with the offset spacer 260 of region (b).

By the process, in region (a), the pre-electrode layer P245, the pre-metal layer P243, the pre-gate dielectric layer P241, and the pre-channel layer P230 may remain as the electrode layer 245, the metal layer 243, the gate dielectric layer 241, and the channel layer 230, respectively.

In FIG. 13, it is illustrated that, in region (a), regions of the pre-channel layer P230 (see FIG. 12), except for a portion vertically overlapping the first gate capping pattern P247_1, are all removed, leaving only the final channel layer 230. However, this is merely an example, and the inventive concept is not limited thereto. That is, in addition to the channel layer 230 illustrated in FIG. 13, a portion of the pre-channel layer P230 may remain together in at least a portion of the upper surface of the active region 212.

FIG. 14A is an enlarged view of EX1 in region (a) of FIG. 13, and FIG. 14B is an enlarged view of EX2 in region (b) of FIG. 13.

In embodiments, the second offset spacer 260 may include SiN. In embodiments, the second offset spacer 260 may be formed with a conformal thickness. For example, the second offset spacer 260 may be formed with a thickness of 10 Å to 70 Å. For example, the second offset spacer 260 may be formed with a thickness of 20 Å, but the inventive concept is not limited thereto.

In some embodiments, the second offset spacer 260 and the first offset spacer 250 may include substantially the same material. In some embodiments, the thickness of the second offset spacer 260 may be less than the thickness of the first offset spacer 250, but the inventive concept is not limited thereto.

Referring to FIG. 14B, the interface film 270 may be located between the first offset spacer 250 and the second offset spacer 260. In embodiments, the interface film 270 may include an oxide, for example, SiO₂.

The interface film 270 may have a very small thickness compared to the first offset spacer 250 and the second offset spacer 260. In some embodiments, during the process of forming the second offset spacer 260 at least partially covering the first offset spacer 250 after forming the first offset spacer 250 including SiN, the interface film 270 may be naturally formed. That is, the interface film 270 may be a film that appears due to forming offset spacers a plurality of times (at least twice) in region (b). In the case of region (a), because the second offset spacer 260 is formed after the first offset spacer layer 250L is completely removed (see FIGS. 12 and 13), the interface film 270 may not be formed, but the inventive concept is not limited thereto. The case in which an interface film is formed in region (a) may be described below with reference to FIG. 17.

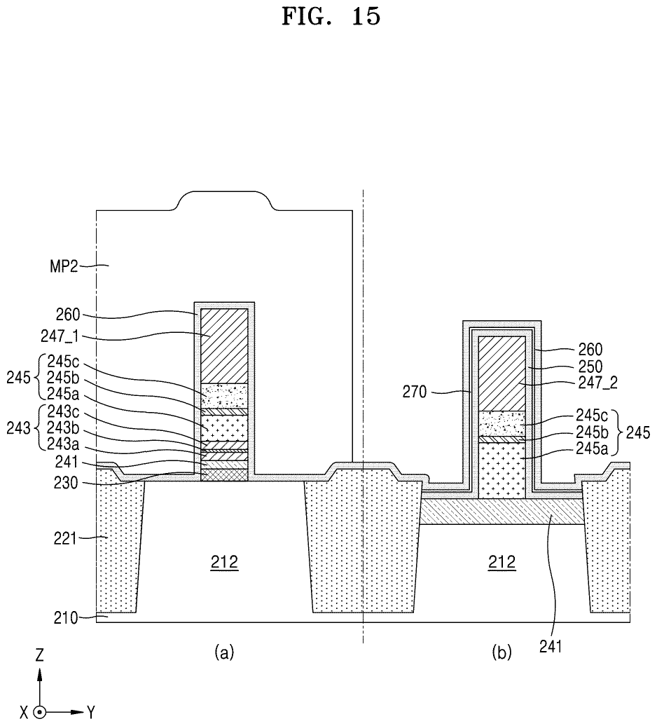

Referring to FIG. 15, a second mask pattern MP2 at least partially covering region (a) may be formed, and an ion implantation process and a low-concentration doping region (not shown) formation process may be performed in region (b).

In embodiments, the low-concentration doping region may include a portion extending vertically downward (a −Z direction) within the active region 212 defined by the device isolation film 221.

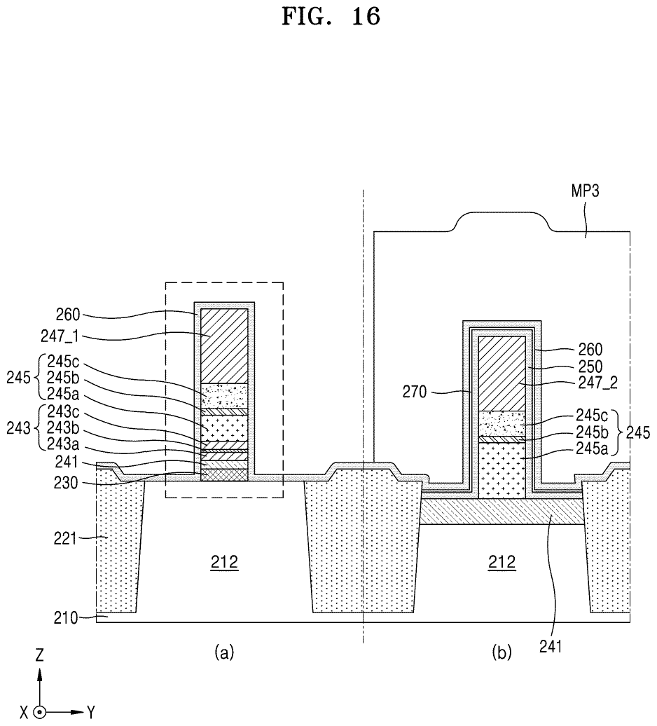

Referring to FIG. 16, a third mask pattern MP3 at least partially covering region (b) may be formed, and an ion implantation process and a low-concentration doping region (not shown) formation process may be performed in region (a).

In embodiments, the low-concentration doping region may include a portion extending vertically downward (the −Z direction) within the active region 212 defined by the device isolation film 221.

Referring to FIGS. 15 and 16 together, in region (a), only the second offset spacer 260 is formed, whereas, in region (b), both the first offset spacer 250 and the second offset spacer 260 are formed. Therefore, because the thicknesses of the offset spacers formed in the two regions are different, the process conditions of region (a) may be different from the process conditions of region (b). That is, the depth at which a dopant is injected may also differ depending on the thickness difference of the offset spacers during the ion implantation process. Accordingly, after forming the second mask pattern MP2 in region (a) and performing an ion implantation process and a low-concentration doping region formation process for region (b) (see FIG. 15), the third mask pattern MP3 may be formed in region (b) and an ion implantation process and a low-concentration doping region formation process may be performed for region (a) (see FIG. 16).

After performing the processes described above with reference to FIGS. 15 and 16, the third mask pattern MP3 may be removed, a portion of the second offset spacer 260 on the upper surface of the first gate capping pattern 247_1 of region (a) and a portion of the first and second offset spacers 250 and 260 on the upper surface of the second gate capping pattern 247_2 of region (b) may be removed so that the upper surfaces of the first and second gate capping patterns 247_1 and 247_2 are exposed, respectively, and the gate spacer 280 may be formed in region (a) and region (b), thereby obtaining the first transistor TR1 and the second transistor TR2 as illustrated in FIG. 8.

In embodiments, the gate spacer 280 may be formed to surround a vertical extension of the second offset spacer 260 in region (a) and region (b). In embodiments, the gate spacer 280 may include an oxide, unlike the first and second offset spacers 250 and 260 including SiN.

FIG. 17 is another enlarged view of the EX1 area in FIG. 13.

Referring to FIG. 17, unlike the enlarged view of the EX1 region of FIG. 13 shown in FIG. 14A, a first offset spacer residual layer 250′and the interface film 270 may be further included on the upper surface and sidewalls of the first gate capping pattern 247_1.

In the manufacturing method of the first transistor TR1 (see FIG. 8) described above with reference to FIGS. 9, 10, 11, 12, 13, 14A, 14B, 15, and 16, the second offset spacer 260 is formed after the first offset spacer layer 250L (see FIG. 12) is completely removed in region (a) (see FIG. 13), but in some cases, a portion of the first offset spacer layer 250L may remain on the upper surface and sidewalls of the first gate capping pattern 247_1 without being removed.

Accordingly, when a portion of the first offset spacer layer 250L is left, the thin first offset spacer residual layer 250′ may remain on the first gate capping pattern 247_1, and in the process of forming the second offset spacer 260 by the first offset spacer residual layer 250′, the interface film 270 may be formed between the first offset spacer residual layer 250′ and the second offset spacer 260.

Because the first offset spacer layer 250L (see FIG. 12) is formed on the sidewalls and upper surface of the first gate capping pattern 247_1, the first offset spacer residual layer 250′that remains as a portion of the first offset spacer layer 250L is not removed but remains may not be formed on the sidewalls of the electrode layer 245, the sidewalls of the metal layer 243, the sidewalls of the gate dielectric layer 241, and the sidewalls of the channel layer 230.

In embodiments, the interface film 270 of FIG. 17 may have substantially the same configuration as that of the interface film 270 of FIG. 14B.

In addition, although it is illustrated in FIG. 17 that the first offset spacer residual layer 250′ surrounds both the sidewalls and the upper surface of the first gate capping pattern 247_1, this is merely an example, and the first offset spacer residual layer 250′ may partially remain only on portions of the sidewalls and the upper surface of the first gate capping pattern 247_1. In the case, the interface film 270 may also be partially formed.

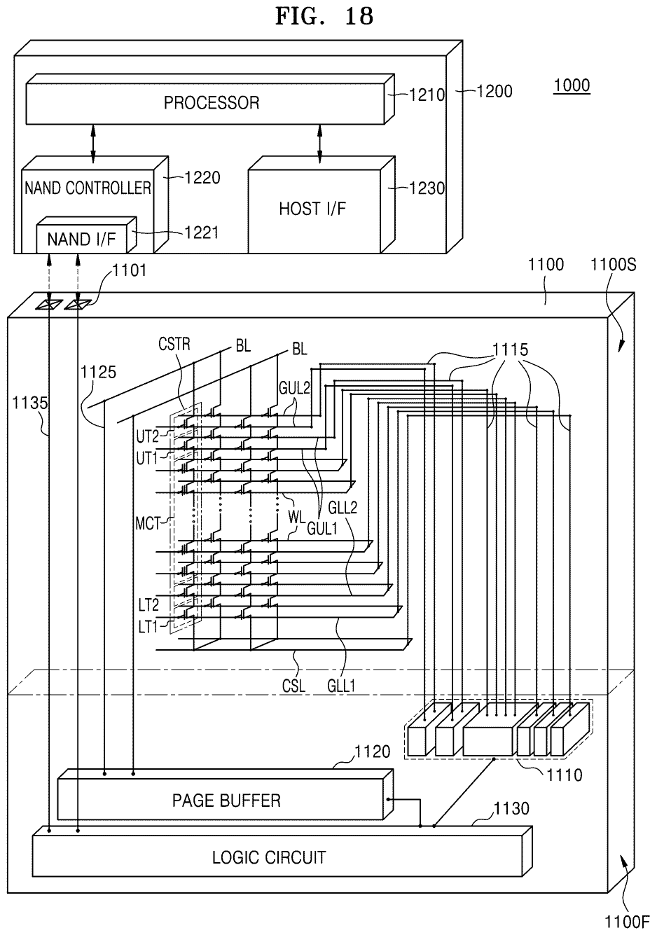

FIG. 18 is a schematic diagram of an electronic system 1000 including a nonvolatile memory device according to the inventive concept.

In embodiments, the electronic system 1000 may include a nonvolatile memory device 1100 and a controller 1200 electrically connected to the nonvolatile memory device 1100. The electronic system 1000 may be a storage device including one or a plurality of nonvolatile memory devices 1100 or an electronic device including a storage device. For example, the electronic system 1000 may be a solid state drive (SSD), a universal serial bus (USB), a computing system, a medical device, or a communication device including at least one nonvolatile memory device 1100.

For example, the nonvolatile memory device 1100 may be a NAND flash memory device including the structure described above with respect to the nonvolatile memory device 100. The nonvolatile memory device 1100 may include a first structure 1100F and a second structure 1100S on the first structure 1100F. In embodiments, the first structure 1100F may be located next to the second structure 1100S. The first structure 1100F may be a peripheral circuit structure including a decoder circuit 1110, a page buffer 1120, and a logic circuit 1130. The second structure 1100S may be a memory cell structure including a bit line BL, a common source line CSL, a plurality of word lines WL, first and second gate upper lines GUL1 and GUL2, first and second gate lower lines GLL1 and GLL2, and a plurality of memory cell strings CSTR between the bit line BL and the common source line CSL.

In the second structure 1100S, the memory cell strings CSTR may include lower transistors LT1 and LT2 adjacent to the common source line CSL, upper transistors UT1 and UT2 adjacent to the bit line BL, and a plurality of memory cell transistors MCT located between the lower transistors LT1 and LT2 and the upper transistors UT1 and UT2. The number of lower transistors LT1 and LT2 and the number of upper transistors UT1 and UT2 may be variously modified according to embodiments.

In embodiments, the upper transistors UT1 and UT2 may include a string select transistor, and the lower transistors LT1 and LT2 may include a ground select transistor. The gate lower lines GLL1 and GLL2 may be gate electrodes of the lower transistors LT1 and LT2, respectively. The word line WL may be a gate electrode of the memory cell transistor MCT, and the gate upper lines GUL1 and GUL2 may be gate electrodes of the upper transistors UT1 and UT2.

The common source line CSL, the gate lower lines GLL1 and GLL2, the word lines WL, and the gate upper lines GUL1 and GUL2 may be electrically connected to the decoder circuit 1110 through a plurality of first connection wirings 1115 extending from the first structure 1100F to the second structure 1100S. The bit lines BL may be electrically connected to the page buffer 1120 through a plurality of second connection wirings 1125 extending from the first structure 1100F to the second structure 1100S.

In the first structure 1100F, the decoder circuit 1110 and the page buffer 1120 may perform a control operation on at least one of the memory cell transistors MCT. The decoder circuit 1110 and the page buffer 1120 may be controlled by the logic circuit 1130.

The nonvolatile memory device 1100 may communicate with the controller 1200 through the I/O pad 1101 electrically connected to the logic circuit 1130. The I/O pad 1101 may be electrically connected to the logic circuit 1130 through an I/O connection wiring 1135 extending from the first structure 1100F to the second structure 1100S.

The controller 1200 may include a processor 1210, a NAND controller 1220, and a host interface (I/F) 1230. In some embodiments, the electronic system 1000 may include a plurality of nonvolatile memory devices 1100, and in this case, the controller 1200 may control the nonvolatile memory devices 1100.

The processor 1210 may control the operation of the electronic system 1000 including the controller 1200. The processor 1210 may operate according to certain firmware and may access the nonvolatile memory device 1100 by controlling the NAND controller 1220. The NAND controller 1220 may include a NAND interface 1221 that handles communication with the nonvolatile memory device 1100. Through the NAND interface 1221, a control command for controlling the nonvolatile memory device 1100, data to be written to the memory cell transistors MCT of the nonvolatile memory device 1100, and data to be read from a plurality of memory cell transistors MCT of the nonvolatile memory device 1100 may be transmitted. The host I/F 1230 may provide a communication function between the electronic system 1000 and an external host. When a control command is received from an external host through the host I/F 1230, the processor 1210 may control the nonvolatile memory device 1100 in response to the control command.

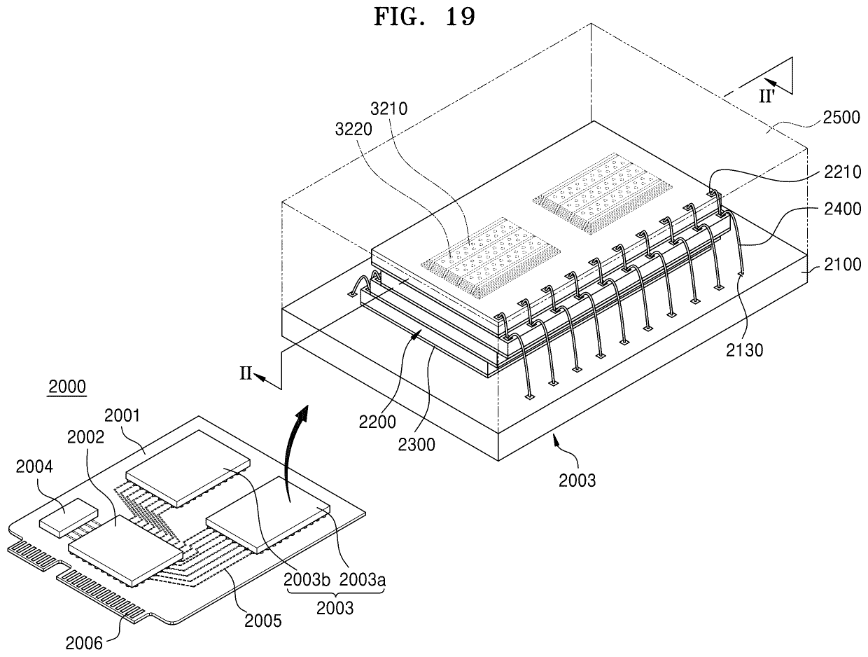

FIG. 19 is a perspective view schematically illustrating an electronic system 2000 including a nonvolatile memory device according to an embodiment.

In embodiments, the electronic system 2000 may include a main board 2001, a controller 2002 mounted on the main board 2001, one or more semiconductor packages 2003, and DRAM 2004. The semiconductor package 2003 and the DRAM 2004 may be connected to the controller 2002 by a plurality of wiring patterns 2005 formed on the main board 2001.

The main board 2001 may include a connector 2006 including a plurality of pins coupled to an external host. The number and arrangement of the pins of the connector 2006 may vary depending on a communication interface between the electronic system 2000 and the external host. In embodiments, the electronic system 2000 may communicate with an external host according to any one of interfaces such as a universal serial bus (USB), a peripheral component interconnect express (PCI-Express), a serial advanced technology attachment (SATA), M-Phy for a universal flash storage (UFS), etc. In embodiments, the electronic system 2000 may operate by power supplied from an external host through the connector 2006. The electronic system 2000 may further include a power management integrated circuit (PMIC) for distributing power supplied from the external host to the controller 2002 and the semiconductor package 2003.

The controller 2002 may write data to or read data from the semiconductor package 2003 and may improve the operating speed of the electronic system 2000.

The DRAM 2004 may be a buffer memory for mitigating a speed difference between the semiconductor package 2003 as a data storage space and the external host. The DRAM 2004 included in the electronic system 2000 may also operate as a kind of cache memory and may provide a space for temporarily storing data in a control operation for the semiconductor package 2003. When the DRAM 2004 is included in the electronic system 2000, the controller 2002 may further include a DRAM controller for controlling the DRAM 2004 in addition to the NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, a plurality of semiconductor chips 2200 on the package substrate 2100, an adhesive layer 2300 positioned on a lower surface of each of the semiconductor chips 2200, a connection structure 2400 electrically connecting the semiconductor chips 2200 to the package substrate 2100, and a molding layer 2500 at least partially covering the semiconductor chips 2200 and the connection structure 2400 on the package substrate 2100.

The package substrate 2100 may be a printed circuit board (PCB) including a plurality of package upper pads 2130. Each of the semiconductor chips 2200 may include an input/output (I/O) pad 2210. The I/O pad 2210 may correspond to the I/O pad 1101 of FIG. 13. Each of the semiconductor chips 2200 may include a plurality of gate stacks 3210 and a plurality of channel structures 3220. Each of the plurality of semiconductor chips 2200 may include at least one nonvolatile memory device 100 described above.

In embodiments, the connection structure 2400 may be a bonding wire electrically connecting the I/O pad 2210 to the package upper pad 2130. Accordingly, in the first and second semiconductor packages 2003a and 2003b, the semiconductor chips 2200 may be electrically connected to each other by a bonding wire method and may be electrically connected to the package upper pad 2130 of the package substrate 2100. In embodiments, in the first and second semiconductor packages 2003a and 2003b, the semiconductor chips 2200 may be electrically connected to each other by a connection structure including a through-silicon via (TSV), instead of the bonding wire type connection structure 2400.

In embodiments, the controller 2002 and the semiconductor chips 2200 may be included in a single package. In embodiments, the controller 2002 and the semiconductor chips 2200 may be mounted on a separate interposer substrate that is different from the main board 2001, and the controller 2002 may be connected to the semiconductor chips 2200 by a wiring formed on the interposer substrate.

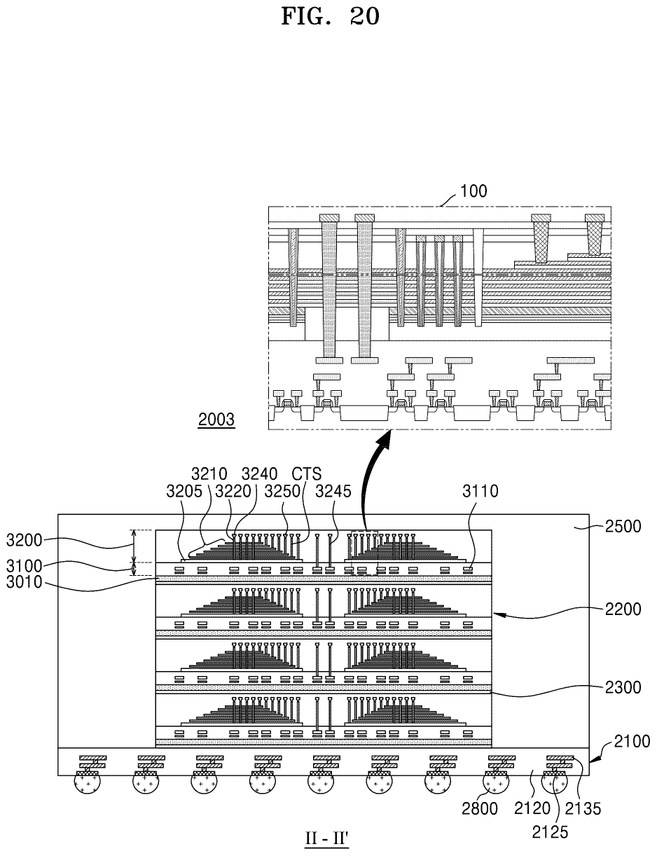

FIG. 20 is a cross-sectional view schematically illustrating semiconductor packages according to an embodiment. FIG. 20 illustrates a configuration taken along line II-II′ of FIG. 19 in detail.

In embodiments, in a semiconductor package 2003, the package substrate 2100 may be PCB. The package substrate 2100 may include a package substrate body portion 2120, a plurality of package upper pads 2130 (refer to FIG. 19) positioned on an upper surface of the package substrate body portion 2120, a plurality of lower pads 2125 positioned on a lower surface of the package substrate body portion 2120 or exposed through the lower surface of the package substrate body portion 2120, and a plurality of internal wirings 2135 electrically connecting the upper pads 2130 to the lower pads 2125 inside the package substrate body portion 2120. The upper pads 2130 may be electrically connected to the connection structures 2400. The lower pads 2125 may be connected to the wiring patterns 2005 on the main board 2001 of the electronic system 2000 illustrated in FIG. 19 through a plurality of conductive connection portions 2800.

Each of the semiconductor chips 2200 may include a semiconductor substrate 3010 and a first structure 3100 and a second structure 3200 sequentially stacked on the semiconductor substrate 3010. The first structure 3100 may include a peripheral circuit region including a plurality of peripheral wirings 3110. The second structure 3200 may include a common source line 3205, a gate stack 3210 on the common source line 3205, a channel structure 3220 passing through the gate stack 3210, and a bit line 3240 electrically connected to the channel structure 3220. In embodiments, each of the plurality of semiconductor chips 2200 may include a configuration as described above for the nonvolatile memory device 100 described above.

Each of the semiconductor chips 2200 may include a through-wiring 3245 electrically connected to the peripheral wirings 3110 of the first structure 3100 and extending into the second structure 3200. The through-wiring 3245 may be located outside the gate stack 3210. In other embodiments, the semiconductor package 2003 may further include a through-wiring passing through the gate stack 3210. Each of the semiconductor chips 2200 may further include an I/O pad (2210 of FIG. 19) electrically connected to the peripheral wirings 3110 of the first structure 3100.

While the inventive concept has been particularly shown and described with reference to embodiments thereof, it will be understood that various changes in form and details may be made therein without departing from the scope of the following claims.

What is claimed is:

1. A nonvolatile memory device comprising:
a peripheral circuit comprising a first transistor and a second transistor,
wherein the first transistor and the second transistor are each on an active region of a substrate,
wherein the first transistor comprises:
a channel layer on the active region;
a first gate dielectric layer on the channel layer;
a metal layer on the first gate dielectric layer;
a first electrode layer on the metal layer;
a first gate capping pattern on the first electrode layer; and
a first offset spacer on sidewalls of the channel layer, the first gate dielectric layer, the metal layer, the first electrode layer, and the first gate capping pattern, and extending on an upper surface of the active region, and
wherein the second transistor comprises:
a second gate dielectric layer on the active region;
a second electrode layer on the second gate dielectric layer;
a second gate capping pattern on the second electrode layer;
a second offset spacer on sidewalls of the second electrode layer and the second gate capping pattern and extending on an upper surface of the second gate dielectric layer; and
a third offset spacer on the second offset spacer,
wherein the first offset spacer and the third offset spacer extend conformally.

2. The nonvolatile memory device of claim 1, wherein the first offset spacer, the second offset spacer, and the third offset spacer comprise SiN.

3. The nonvolatile memory device of claim 1, wherein the first transistor comprises a low-voltage transistor, and wherein the second transistor comprises a high-voltage transistor.

4. The nonvolatile memory device of claim 1, wherein
the first offset spacer extends along a sidewall of the first transistor in a first direction and extends along the upper surface of the active region in a second direction perpendicular to the first direction, and
the second offset spacer and the third offset spacer extend along a sidewall of the second transistor in the first direction and extend along the upper surface of the second gate dielectric layer in the second direction.

5. The nonvolatile memory device of claim 1, wherein a second thickness of the second offset spacer and a third thickness of the third offset spacer are in a range of 10 Å to 70 Å.

6. The nonvolatile memory device of claim 1, wherein a second thickness of the second offset spacer is in a range of 10 Å to 70 Å.

7. The nonvolatile memory device of claim 1, wherein a second thickness of the second offset spacer is greater than a first thickness of the first offset spacer and a third thickness of the third offset spacer.

8. The nonvolatile memory device of claim 1, wherein the second transistor further comprises an interface film between the second offset spacer and the third offset spacer.

9. The nonvolatile memory device of claim 8, wherein the interface film comprises SiO₂.

10. The nonvolatile memory device of claim 1, wherein each of the first transistor and the second transistor further comprises a gate spacer on sidewalls of the first and third offset spacers.

11. The nonvolatile memory device of claim 10, wherein the gate spacer comprises SiO₂.

12. The nonvolatile memory device of claim 1, wherein a length of the first transistor is greater than a length of the second transistor in a direction perpendicular to an upper surface of the substrate.

13. The nonvolatile memory device of claim 1, wherein the first transistor comprises a PMOS transistor.

14. A nonvolatile memory device comprising:
a peripheral circuit comprising a substrate;
a memory cell array on the peripheral circuit;
wherein the peripheral circuit comprises a first transistor and a second transistor spaced apart from each other and on an active region defined by a device isolation film on the substrate,
wherein the first transistor comprises:
a first gate structure on the active region;
a first offset spacer extending in a first direction parallel to an upper surface of the substrate on an upper surface of the active region and extending in a second direction perpendicular to the first direction on a sidewall of the first gate structure; and
a first gate spacer on a sidewall of the first offset spacer,
wherein the second transistor comprises:
a gate dielectric layer on the active region;
a second gate structure on the gate dielectric layer;
a second offset spacer extending in the first direction on an upper surface of the gate dielectric layer and extending in the second direction on a sidewall of the second gate structure;
a third offset spacer between the second offset spacer and the second gate structure, between the second offset spacer and the gate dielectric layer;
a second gate spacer on a sidewall of the second offset spacer opposite the sidewall of the first offset spacer in the first direction; and
an interface film between the second offset spacer and the third offset spacer,
wherein the first offset spacer and the second offset spacer extend conformally.

15. The nonvolatile memory device of claim 14, wherein
the first transistor is a low-voltage transistor, wherein the second transistor is a high-voltage transistor, wherein the gate dielectric layer in the second transistor comprises SiON, and wherein a thickness in the second direction of the gate dielectric layer is 200 Å or more.

16. The nonvolatile memory device of claim 14, wherein the first offset spacer, the second offset spacer, and the third offset spacer comprise SiN, and wherein the first gate spacer and the second gate spacer comprise SiO₂.

17. The nonvolatile memory device of claim 14, wherein thicknesses of the first offset spacer, the second offset spacer, and the third offset spacer are in a range of 10 Å to 70 Å.

18. The nonvolatile memory device of claim 17, wherein a thickness of the third offset spacer is greater than a thickness of the second offset spacer and a thickness of the first offset spacer.

19. A nonvolatile memory device comprising:
a peripheral circuit comprising a plurality of transistors on a substrate; and
a memory cell array controlled by the peripheral circuit,
wherein the plurality of transistors comprise a first transistor and a second transistor,
wherein the first transistor and the second transistor each comprise a first gate structure and a second gate structure extending in a first direction parallel to the substrate and on an active region defined by a device isolation film on the substrate, wherein the first gate structure and second gate structure are spaced apart from each other in a second direction intersecting the first direction,
wherein the first gate structure and the second gate structure each comprise an electrode layer comprising a polysilicon electrode and a gate capping pattern on the electrode layer,
wherein the first transistor comprises a first offset spacer extending along a sidewall of the first gate structure in a third direction perpendicular to the first direction and the second direction and extending along an upper surface of the active region in the second direction, and a gate spacer on a sidewall of the first offset spacer,
wherein the second transistor comprises a second offset spacer having a second thickness in a range of 10 Å to 70 Å, extending along a sidewall of the second gate structure in the third direction, and extending along an upper surface of the active region in the second direction, a third offset spacer on the second offset spacer, and a gate spacer on the third offset spacer,
wherein a first thickness of the first offset spacer and a third thickness of the third offset spacer are in the range of 10 Å to 70 Å and the first offset spacer and the third offset spacer extend conformally,
wherein an interface film is between the third offset spacer and the second offset spacer, and
wherein a residual offset spacer is between the first offset spacer and a sidewall and an upper surface of the gate capping pattern in the first gate structure.

20. The nonvolatile memory device of claim 19, wherein
the residual offset spacer has a fourth thickness less than the second thickness of the second offset spacer, and
wherein a SiO₂ interface film is between the residual offset spacer and the first offset spacer.
